(19) United States
(12) Patent Application Publication
(10) Pub. No.: US 2014/0130742 A1
(43) Pub. Date: May 15, 2014

(54) APPARATUS AND METHOD FOR DEPOSITION

(71) Applicants: Seok Min Kang, Seoul (KR); Moo Seong Kim, Seoul (KR)

(72) Inventors: Seok Min Kang, Seoul (KR); Moo Seong Kim, Seoul (KR)

(73) Assignee: LG INNOTEK CO., LTD., Seoul (KR)

(21) Appl. No.: 14/128,841

(22) PCT Filed: Jun. 25, 2012
(86) PCT No.: PCT/KR2012/004993

§ 371 Date: Dec. 23, 2013

(30) Foreign Application Priority Data
Jun. 23, 2011 (KR) 10-2011-0061398
Oct. 28, 2011 (KR) 10-2011-0110902

(51) Int. Cl. C23C 16/448

(52) U.S. Cl. CPC C23C 16/448
USPC 118/724; 118/715

(57) ABSTRACT

Disclosed are a deposition apparatus and a deposition method. The deposition apparatus comprises a generator to produce an intermediate compound by using a source material, a storage part to collect and store the intermediate compound, and a reaction part in which the intermediate compound is introduced and reaction of the intermediate compound occurs. The deposition method comprises producing an intermediate compound by using a source material, collecting and storing the intermediate compound, and introducing the intermediate compound into a reaction furnace and allowing the intermediate compound to react to a substrate or a wafer.

### TECHNICAL FIELD

The embodiment relates to a deposition apparatus and a deposition method.

### BACKGROUND ART

In general, among technologies to form various thin films on a substrate or a wafer, a CVD (Chemical Vapor Deposition) scheme has been extensively used. The CVD scheme results in a chemical reaction. According to the CVD scheme, a semiconductor thin film or an insulating layer is formed on a wafer surface by using the chemical reaction of a source material.

The CVD scheme and the CVD device have been spotlighted as an important thin film forming technology due to the fineness of the semiconductor device, power device and the development of high-power and high-efficiency LED. Recently, the CVD scheme has been used to deposit various thin films, such as a silicon layer, an oxide layer, a silicon nitride layer, a silicon oxynitride layer, or a tungsten layer, on a wafer.

According to the related art, feeding gas is changed to a radical in a reaction part, and an activation process to a radical is additionally required in order to change the feeding gas into the radical. Therefore, when performing an epi-wafer deposition process, several process steps are required. Accordingly, the process time and the process efficiency may be degraded.

Therefore, a novel deposition apparatus capable of omitting the activation process to the radical in the deposition process and a method for the same are required.

### DISCLOSURE OF INVENTION

### Technical Problem

The embodiment provides a deposition apparatus capable of simplifying the structure of a reaction furnace and forming a high-quality thin film and a deposition method.

### Solution to Problem

According to the embodiment, there is provided a deposition apparatus. The deposition apparatus comprises a generator to produce an intermediate compound by using a source material, a storage part to collect and store the intermediate compound, and a reaction part in which the intermediate compound is introduced and reaction of the intermediate compound occurs.

According to the embodiment, there is provided a deposition method. The deposition method comprises producing an intermediate compound by using a source material, collecting and storing the intermediate compound, and introducing the intermediate compound into a reaction furnace and allowing the intermediate compound to react to a substrate or a wafer.

### Advantageous Effects of Invention

As described above, according to the embodiment, the deposition apparatus comprises an intermediate compound generator and an intermediate compound storage part. The storage part collects and stores the intermediate compound produced by the generator and supplies the intermediate compound to the reaction part through the control valve.

Since the intermediate compound is supplied to the reaction part, the reaction can stably occur in the reaction part. In addition, a radical atom serving as the intermediate compound is stably deposited on the substrate provided in the reaction part, so that the high-quality thin film can be formed. In addition, the chemical reaction can be stably induced, so that the growing rate of the thin film can be increased, and the thin film can be effectively controlled.

According to the related art, the feeding gas is changed to the radical in the reaction part, and the activation process to the radical is additionally required for the change to the radical.

However, according to the present embodiment, before the feeding gas is supplied to the reaction part, the feeding gas is decomposed to produce the intermediate compound. Accordingly, the activation process to the radical can be omitted.

Therefore, according to the deposition apparatus and the deposition method, the reaction part can be simply designed and reduced in size.

### BRIEF DESCRIPTION OF DRAWINGS

FIG. 1 is a schematic view showing the structure of a deposition apparatus according to the embodiment;

FIG. 2 is an enlarged view of a part A of FIG. 1;

FIG. 3 is an enlarged view of a part B of FIG. 1;

FIG. 4 is a schematic view showing the structure of a deposition apparatus according to a modified embodiment; and

FIG. 5 is a flowchart showing a method for the deposition according to the embodiment.

### MODE FOR THE INVENTION

In the description of the embodiments, it will be understood that, when a layer (or film), a region, a pattern, or a structure is referred to as being “on” or “under” another substrate, another layer (or film), another region, another pad, or another pattern, it can be “directly” or “indirectly” on the other substrate, layer (or film), region, pad, or pattern, or one or more intervening layers may also be present. Such a position of the layer has been described with reference to the drawings.

The thickness and size of each a layer (or film), each region, each pattern, or each structure shown in the drawings may be exaggerated, omitted or schematically drawn for the purpose of convenience or clarity. In addition, the size of elements does not utterly reflect an actual size.

Hereinafter, the embodiment of the disclosure will be described in detail with reference to accompanying drawings.

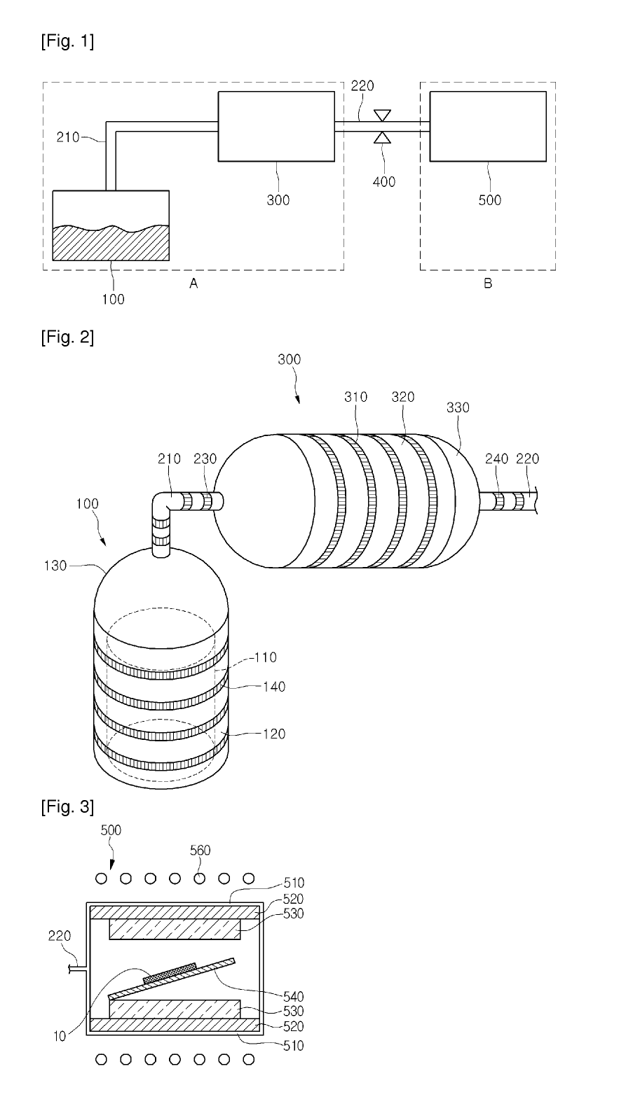

FIG. 1 is a view schematically showing a deposition apparatus according to the present embodiment and showing components of the deposition apparatus in detail. FIG. 2 is a view showing a generator and a storage part according to the present embodiment, and FIG. 3 is a view showing a reaction part according to the present embodiment.

Referring to FIG. 1, the deposition apparatus according to the present embodiment may comprise a generator 100, a storage part 300, and a reaction part 500.

Referring to FIG. 2, the generator 100 according to the present embodiment may comprise an internal container 110 to receive a source material, an external container 120 to surround the internal container 110, and an upper cover 130 which seals the internal container 110 and the external container 120 and is linked with a first feeding line 210.

In addition, the generator 100 may comprise source material feeding lines 150, 160, and 170 to supply the source material into the internal container 110.

The internal container 110 may comprise a source material. The source material may comprise a solid source material, a liquid source material, or a gas source material.

The source material may comprise silicon (Si), chlorine (Cl), or carbon (C). And carbon source comprises acetylene(C₂H₂), methane(CH₄) or propane(C₃H₈). That is, the carbon source comprises a compound comprising carbon(C). Preferably, the source material may comprise silane (SiH₄), hydrogen chloride (HCl), and propane (C₃H₈).

For example, the source material may comprise various source materials containing silicon (Si), such as silicon tetrachloride (SiCl₄), trichlorosilane (TCS)(SiHCl₃), dichlorosilane (SiH₂Cl₂), and silane (SiH₄). Preferably, the source material may comprise silane (SiH₄), hydrogen chloride (HCl), and propane (C₃H₈).

In addition, the source material may comprise methyltrichlorosilane (MTS). The methyltrichlorosilane is a compound expressed in a chemical formula of CH₃SiCl₃. Silicon and carbon are produced from one molecular of the methyltrichlorosilane through decomposition, and the ratio of silicon to carbon is 1:1, so that the methyl-trichlorosilane has an advantage in the deposition of silicon carbide (SiC) in terms of stoichiometry.

The external container 120 and the first feeding line 210 may comprise heating parts 140 and 230. The heating parts 140 and 230 may have the form of a wire surrounding the external container 120 and the first feeding line 210. For example, the heating part 140 and 230 may comprise filaments, coils, or carbon wires.

The source material received in the internal container 110 may be heated by the heating part 140. Preferably, if the source material comprises methyltrichlorosilane, the internal container 110 may be heated at the temperature of 800° C. to 950° C. In addition, if the source material comprises silane (SiH₄), hydrogen chloride (HCl), and propane (C₃H₈), the internal container 110 may be heated at the temperature of about 1000° C. to about 1200° C.

The source material is supplied into the internal container 110 through the source material feeding line and heated by the heating part 140 to produce an intermediate compound comprising carbon (C), silicon (Si), and chlorine (Cl). The intermediate compound may comprise at least one selected from the group of consisting of CH₃., CH₄, SiCl., SiCl₂., SiCl₃., SiHCl. or SiHCl₂.. The intermediate compound produced from the internal container 110, that is the generator 100 is transferred to the storage part 300 through the first feeding line 210 linked with the upper cover 130.

The storage part 300 comprises a container 320 to receive the intermediate compound, an upper cover 330, which seals the container 320 and is linked with a second feeding line 220, and a gas feeding line 180 used to supply carrier gas.

The storage part 300 may collect and store the intermediate compound produced form the generator 100. The storage part 300 and the second feeding line 220 may comprise heating parts 240 and 310. The heating parts 240 and 310 may have the form of a wire surrounding the storage part 300 and the second feeding line 220. For example, the heating parts 240 and 310 may comprise filaments, coils, or carbon wires.

The intermediate compound collected and stored in the storage part 300 is maintained at a proper temperature by the heating part 310, so that the intermediate compound is maintained in a radical state. Preferably, if the source material comprises methyltrichlorosilane, the source material may be maintained at the pressure of about 5 kPa to about 30 kPa at the temperature of about 800° C. to about 950° C. In addition, if the source material comprises silane (SiH₄), hydrogen chloride (HCl), and propane (C₃H₈), the intermediate compound may be maintained at the temperature of about 1100° C. to about 1200° C.

The intermediate compound collected and stored in the storage part 300 is introduced into the reaction part 500 through the second feeding line 220. In this case, in order to transfer the intermediate compound, carrier gas may be supplied through the gas feeding line 180. The carrier gas may preferably comprise hydrogen (H) or helium (He). An amount of the intermediate compound introduced into the reaction part 500 may be controlled by a control valve 400 provided in the second feeding line 220.

Since the intermediate compound is directly supplied to the reaction part 500, the reaction may stably occur in the reaction part 500. In addition, the radical serving as the intermediate compound is stably deposited on a substrate provided in the reaction part 500, so that the high-quality thin film may be formed. In addition, the chemical reaction is stably induced, so that the growing rate of the thin film can be increased, and the thin film can be effectively controlled.

According to the related art, source gas is changed to a radical within a reaction part, and an activation process to the radical is additionally required in order to change the source gas to the radical. According to the present embodiment, before the source gas is supplied to the reaction part 500, the source gas is decomposed to produce the intermediate compound. Accordingly, the activation process to the radical may be omitted. Accordingly, the reaction part can be simply designed and reduced in size.

Referring to FIG. 3, the reaction part 500 may comprise a chamber 510, heating units 560, thermal insulating units 520, susceptors 530, and a substrate holder 540 provided between the susceptors 530. Although FIG. 3 shows only a horizontal-type reaction part, the embodiment is not limited thereto. The embodiment may comprise various reaction parts such as a vertical-type reaction part.

The chamber 510 has a cylindrical shape or a rectangular box shape, and has a predetermined space therein to handle the substrate 10. Although not shown in drawings, a gas exhaust part may be additionally formed at one lateral side of the chamber 510 to exhaust gas.

The chamber 510 prevents external gas from being introduced into the chamber 510 to maintain a vacuum degree. To this end, the chamber 510 may comprise quartz representing superior mechanical strength and superior chemical durability.

Thereafter, the heating units 560 may be provided at the outside of the chamber 510.

The heating units 560 may comprise a resistive heating device to emit heat if power is applied thereto, and may be arranged at a predetermined interval to uniformly heat the substrate 10. In other words, the heating units 550 may have a wire form so that the heating units 550 may be arranged in a predetermined form. For example, the heating units 560 may comprise filaments, coils, or carbon wires.

Thereafter, the thermal insulating units 520 may be provided in the chamber 510. The thermal insulating units 520 conserve heat in the chamber 510. In addition, the thermal insulating units 520 are provided in such a manner that the heat emitted from the heating units 560 may be effectively transferred to the susceptors 530.

Each thermal insulating unit 520 may comprise a material representing chemical stability without being deformed by the heat emitted from the heating units 560. For example, the thermal insulating unit 520 may comprise nitride ceramic, carbide ceramic, or graphite.

Subsequently, the susceptor 530 is positioned on the thermal insulating unit 520.

In the deposition apparatus according to the embodiment, the substrate 10 having a deposit formed thereon or the substrate 10 subject to the epitaxial growth process is placed on the susceptor 530.

Referring to FIG. 3, the susceptor 530 may comprise an upper plate, a lower plate, and lateral side plates. The upper and lower plates of the susceptor 530 face each other.

The susceptor 530 may be manufactured by placing the upper plate and the lower plate, and placing the lateral side plates at both lateral sides of the upper and lower plates and bonding the upper and lower plates with the lateral side plates.

However, the embodiment is not limited thereto. Accordingly, the susceptor 530 may be manufactured by making a space for a gas passage in a rectangular parallelepiped susceptor.

A substrate holder 540 may be provided on the lower plate of the susceptor 530 to fix the substrate 10 to be deposited.

Air flows through the space between the upper and lower plates of the susceptor 530, so that the deposition process may be performed. The lateral side plates of the susceptor 530 prevent reactive gas from leaking from the susceptor 530 when air flows in the susceptor 530.

The susceptor 530 comprises graphite representing a high heat resistance property and a superior workability, so that the susceptor 530 can endure under the high temperature condition. Since the graphite has a porous structure, the graphite may emit occlusion gas during the deposition process. In addition, the graphite reacts to feeding gas, so that the surface of the susceptor may be changed into silicon carbide. Accordingly, the thin film of the susceptor may comprise silicon carbide.

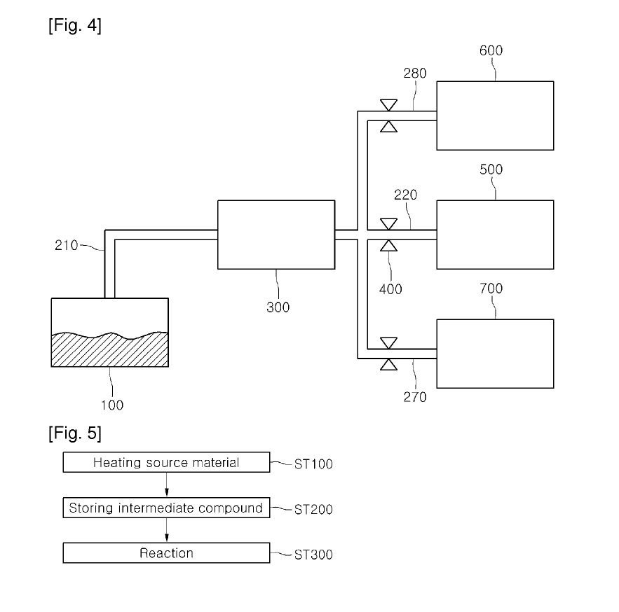

FIG. 4 is a schematic view showing the structure of a deposition apparatus according to a modified embodiment.

Referring to FIG. 4, the storage part 300 is linked with third and fourth feeding lines 270 and 280 as well as the second feeding line 220, so that the intermediate compound can be introduced in a plurality of reaction parts 600 and 700. Therefore, the intermediate compound, which is previously collected and stored, is introduced into the plural reaction parts through one source material device, so that the deposition process can be rapidly performed.

Hereinafter, the deposition method according to the embodiment will be described with reference to FIG. 5. In the following description, the details of structures and components the same as those described above or extremely similar to those described above will be omitted except for only structures and components making the difference from those described above for the purpose of clear and simple explanation.

FIG. 5 is a flowchart showing the deposition method according to the embodiment.

Referring to FIG. 5, the deposition method according to the embodiment comprises a step (step ST100) of producing an intermediate compound by heating a source material, a step (step ST200) of collecting and storing the intermediate compound, and a reaction step (step ST300).

In the step (step ST100) of producing an intermediate compound, the intermediate compound may be produced by using the source material. The intermediate compound may be produced by heating the source material beyond a predetermined temperature. For example, when the source material comprises SiH4, HCl, and C3H8, the source material may be heated at the temperature of 1100° C. to 1200° C. to produce the intermediate compound. In addition, when the source material comprises methyl-trichlorosilane, the source material may be heated at the temperature of 800° C. to 950° C. to produce the intermediate compound.

In the step (step ST200) of collecting and storing the intermediate compound, the intermediate compound may be collected and stored. In this case, in order to maintain the intermediate compound in the radical state, the temperature of the intermediate compound must be constantly maintained in the step (step ST200) of storing the intermediate compound. In order to constantly maintain the temperature of the intermediate compound, a heat member may be provided in the storage part to collect and store the intermediate compound.

For example, when the source material comprises SiH4, HCl, and C3H8, the intermediate compound may be maintained at the temperature of 1100° C. to 1200° C. In addition, when the source material comprises methyltrichlorosilane, the intermediate compound may be maintained at the temperature of 800° C. to 950° C.

Thereafter, in the reaction step (step ST300), the intermediate compound is introduced into the reaction furnace to react to the substrate or the wafer. The intermediate compound comprises silane, and the substrate 10 may comprise silicon carbide.

When introducing the intermediate compound into the reaction part, an amount of the intermediate compound can be controlled by the control valve 400 provided in the second feeding line 220.

In addition, one or a plurality of reaction parts may be provided. Accordingly, the intermediate compound may be introduced one reaction furnace or a plurality of reaction furnaces.

In this case, the thin film deposited on the substrate 10 may comprise silicon carbide. In other words, in the reaction step (step ST300), a silicon carbide epitaxial layer may be formed on the substrate or the wafer.

Processes of producing, storing, and depositing the intermediate compound may be separately performed.

The source material may comprise various source materials containing silicon (Si), such as silicon tetrachloride (SiCl₄), trichlorosilane (TCS)(SiHCl₃), dichlorosilane (SiH₂Cl₂), and silane (SiH₄). Preferably, the source material may comprise silane (SiH₄), hydrogen chloride (HCl), and propane (C₃H₈), and may be changed into a radical. In addition, the source material may comprise methyltrichlorosilane.

The source material is heated to produce at least one selected from the group of consisting of CH₃., CH₄, SiCl., SiCl₂., SiCl₃., SiHCl., or SiHCl₂ serving as the intermediate compound, and the CH3., CH₄, SiCl., SiCl₂., SiCl₃., SiHCl., or SiHCl₂ may be supplied to the substrate 10. Therefore, the thin film can be stably deposited on the substrate 10, so that the high-quality silicon carbide (SiC) thin film may be formed.

Any reference in this specification to “one embodiment,” “an embodiment,” “example embodiment,” etc., means that a particular feature, structure, or characteristic described in connection with the embodiment is comprised in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A deposition apparatus comprising:
a generator to produce an intermediate compound by using a source material;
a storage part to collect and store the intermediate compound; and
a reaction part in which the intermediate compound is introduced and reaction of the intermediate compound occurs.

2. The deposition apparatus of claim 1, wherein the source material comprises silicon (Si), chlorine (Cl), and carbon (C).

3. The deposition apparatus of claim 1, wherein the intermediate compound comprises at least one selected from the group of consisting of CH₃., CH₄, SiCl., SiCl₂., SiCl₃., SiHCl., or SiHCl₂..

4. The deposition apparatus of claim 1, wherein the generator and the storage part are provided at outsides thereof with a heating part.

5. The deposition apparatus of claim 4, wherein the generator and the storage part are maintained at a temperature of 800° C. to 950° C. by the heating part.

6. The deposition apparatus of claim 4, wherein the generator and the storage part are maintained at a temperature of 1100° C. to 1200° C. by the heating part.

7. The deposition apparatus of claim 1, wherein the intermediate compound is introduced into one reaction part or a plurality of reaction parts.

8. The deposition apparatus of claim 1, wherein an introduction amount of the intermediate compound is adjusted by a control valve.

9. The deposition apparatus of claim 1, wherein a silicon carbide (SiC) epitaxial layer is deposited on a substrate or a wafer in the reaction part.

10-16. (canceled)

17. The deposition apparatus of claim 2, wherein the source material comprises silane (SiH₄), hydrogen chloride (HCl), and propane (C₃H₈).

18. The deposition apparatus of claim 2, wherein the source material comprises methyltrichlorosilane (MTS).

19. The deposition apparatus of claim 4, wherein the heating part comprises filaments, coils, or carbon wires.

20. The deposition apparatus of claim 5, wherein the intermediate compound collected and stored in the storage part is maintained by the heating part so that the intermediate compound is maintained in a radical state.

21. The deposition apparatus of claim 6, wherein the intermediate compound collected and stored in the storage part is maintained by the heating part so that the intermediate compound is maintained in a radical state.
